(19) United States
(12) Patent Application Publication
(10) Pub. No.: US 2025/0266269 A1
(43) Pub. Date: Aug. 21, 2025

(54) SUBSTRATE PROCESSING APPARATUS AND SUBSTRATE PROCESSING METHOD

(71) Applicant: Tokyo Electron Limited, Tokyo (JP)

(72) Inventors: Tsunenaga NAKASHIMA, Koshi City (JP); Naoya TATEISHI, Koshi City (JP); Keita MATSUMOTO, Koshi City (JP)

(21) Appl. No.: 19/056,816

(22) Filed: Feb. 19, 2025

(30) Foreign Application Priority Data
Feb. 21, 2024 (JP) 2024-024823

(51) Int. Cl. H01L 21/67; B08B 5/00; B08B 13/00; B08B 15/02; H01L 21/02

(52) U.S. Cl. CPC H01L 21/67028; B08B 5/00; B08B 13/00; B08B 15/02; H01L 21/02057

(57) ABSTRACT

A substrate processing apparatus includes: a processing container having an internal processing space which is depressurized to a pressure lower than atmospheric pressure, and an opening through which a substrate is loaded into and unloaded from the processing space; a substrate holding/rotating mechanism configured to horizontally hold the substrate and including a substrate holder for holding the substrate inside the processing space and a driving force source configured to generate a driving force for rotationally driving the substrate holder; a housing having an internal space hermetically isolated from the processing space; a horizontal movement mechanism configured to move the housing in a horizontal direction so as to move the substrate holder in the horizontal direction; and a gas nozzle configured to inject a gas so as to irradiate a gas cluster onto an upper surface of the substrate held by the substrate holder.

### CROSS-REFERENCE TO RELATED APPLICATION

This application is based upon and claims the benefit of priority from Japanese Patent Application No. 2024-024823, filed on Feb. 21, 2024, the entire contents of which are incorporated herein by reference.

### TECHNICAL FIELD

The present disclosure relates to a substrate processing apparatus and a substrate processing method.

### BACKGROUND

In manufacturing semiconductor devices, the adhesion of particles to a substrate is a factor that deteriorates product yield. For this reason, before and after substrate processing such as film formation, cleaning of the substrate is performed to remove such particles. Methods of cleaning the substrate include wet cleaning and dry cleaning. Gas cluster cleaning is one type of dry cleaning. The gas cluster cleaning is a method in which a gas cluster is irradiated onto a surface of the substrate placed inside a vacuum processing chamber, and the physical energy of the gas cluster peels off the particles adhered to the surface of the substrate.

An apparatus for performing the gas cluster cleaning is disclosed in, for example, Patent Document 1. The apparatus disclosed in Patent Document 1 adjusts an irradiation position of the gas cluster by moving a stage which holds a substrate using an XY table equipped with an X-axis rail and a Y-axis rail. The stage and the XY table are exposed to an internal atmosphere of a vacuum processing chamber.

### PRIOR ART DOCUMENT

### Patent Document

Patent Document 1: Japanese Laid-Open Patent Publication No. 2015-026745

### SUMMARY

According to one embodiment of the present disclosure, a substrate processing apparatus includes: a processing container having a processing space provided in an interior of the processing container, which is depressurized to a pressure lower than atmospheric pressure, and an opening through which a substrate is loaded into and unloaded from the processing space; a substrate holding/rotating mechanism configured to hold the substrate in a horizontal posture and rotate the substrate around a vertical axis, and including a substrate holder configured to hold the substrate inside the processing space and a driving force source configured to generate a driving force for rotationally driving the substrate holder; a housing having an internal space hermetically isolated from the processing space, wherein the driving force source of the substrate holding/rotating mechanism is accommodated in the internal space; a horizontal movement mechanism configured to move the housing in a horizontal direction so as to move the substrate holder in the horizontal direction; and a gas nozzle configured to inject a gas so as to irradiate a gas cluster onto an upper surface of the substrate held by the substrate holder.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a schematic transverse cross-sectional view of a substrate processing system according to an embodiment of a substrate processing apparatus.

FIG. 2A is a schematic longitudinal cross-sectional view illustrating an embodiment of a gas cluster cleaning unit incorporated in the substrate processing system, which schematically illustrates a state when a gas cluster cleaning is performed on a substrate.

FIG. 2B is a view schematically illustrating a state in which the substrate is loaded into or unloaded from a processing container in the gas cluster cleaning unit illustrated in FIG. 2A.

FIG. 3A is a plan view illustrating a configuration example of the gas cluster cleaning unit in which a ceiling wall is removed from the processing container, which illustrates a state in which a housing and a rotational stage are at a substrate transfer position.

FIG. 3B is a view illustrating a state in which the housing and the rotational stage are at a substrate processing position in the gas cluster cleaning unit illustrated in FIG. 3A.

FIG. 4 is a view illustrating a gas nozzle and a gas supply mechanism.

FIGS. 5A to 5F are operational views illustrating a transition of a positional relationship between the processing chamber, the substrate, and the gas nozzle as viewed directly from above when the substrate is loaded or unloaded and the substrate is processed.

FIG. 6 is a longitudinal cross-sectional view illustrating another embodiment of the gas cluster cleaning unit.

### DETAILED DESCRIPTION

Hereinafter, a configuration of a substrate processing system 100 according to an embodiment of a substrate processing apparatus will be described with reference to the accompanying drawings. In this specification and drawings, for the clarification of a positional relationship, an XYZ orthogonal coordinate system in which an X-axis direction, a Y-axis direction, and a Z-axis direction are orthogonal to one another is defined, and descriptions will be given with reference to this coordinate system as necessary. A positive Z-axis direction is defined as a vertical upward direction. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and constituent elements have not been described in detail so as not to unnecessarily obscure aspects of the various embodiments.

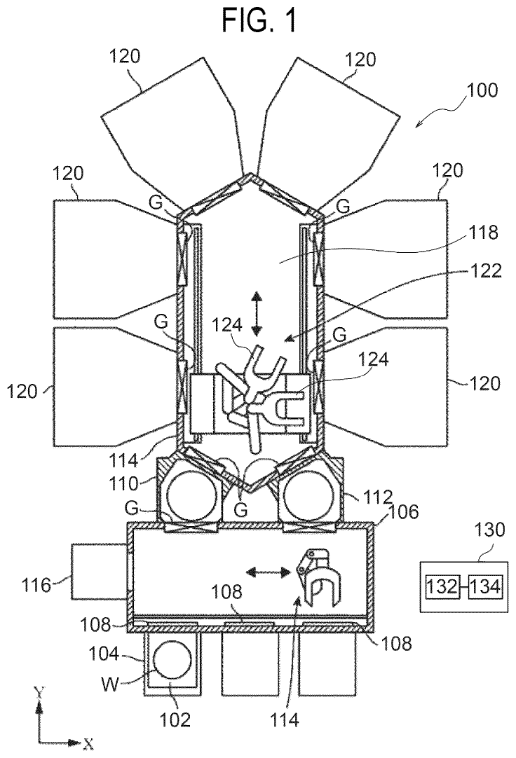

As illustrated in FIG. 1, the substrate processing system 100 includes three loading/unloading ports 104 arranged in the X-axis direction. A front opening unified pod (FOUP) 102, which is a sealed substrate transfer container accommodating, for example, 25 substrates W (for example, semiconductor wafers), is placed on each of the three loading/unloading ports 104. An atmospheric transfer chamber 106 kept at atmospheric pressure is provided on an inner side of the loading/unloading ports 104. A gate door 108, which is opened and closed together with a lid of the FOUP 102, is provided on a front wall of the atmospheric transfer chamber 106.

Two load lock chambers 110 and 112 are connected to a rear wall of the atmospheric transfer chamber 106. An internal atmosphere of each of the load lock chambers 110 and 112 may be switched between a normal pressure (atmospheric pressure) atmosphere and a medium vacuum atmosphere of about 1 Pa by a vacuum pump and a leak valve (all not illustrated). In FIG. 1, a member designated by reference symbol G denotes a gate valve.

The atmospheric transfer chamber 106 is provided with a first substrate transfer mechanism 114 for transferring the substrate W. An alignment chamber 116 is connected to a left wall of the atmospheric transfer chamber 106. The alignment chamber 116 is provided with an aligner (not illustrated) for aligning a notch of the substrate W. The first substrate transfer mechanism 114 delivers the substrate W to the FOUP 102, the load lock chambers 110 and 112, and the alignment chamber 116.

A vacuum transfer chamber 118 is connected to rear sides of the load lock chambers 110 and 112. The vacuum transfer chamber 118 is suctioned by a vacuum pump (not illustrated) and maintained at a medium vacuum of, for example, about 1 Pa.

A plurality of processing units 120 is connected to the vacuum transfer chamber 118. At least one of the plurality of processing units 120 is a gas cluster cleaning unit 10 described later. At least one of the other processing units 120 may be, for example, a vacuum bake unit for removing organic compounds from the substrate W before a gas cluster cleaning is performed. At least one of the other processing units 120 may be a film formation unit which performs a vacuum film formation process based on chemical vapor deposition (CVD) or sputtering with respect to the substrate W that has been subjected to the gas cluster cleaning.

The vacuum transfer chamber 118 is provided with a second substrate transfer mechanism 122 for transferring the substrate W. For example, the second substrate transfer mechanism 122 includes a substrate holder 124 of a fork shape, which functions as an end effector. The second substrate transfer mechanism 122 delivers the substrate W to the load lock chambers 110 and 112, and the processing units 120.

The substrate processing system 100 is provided with a control device 130. The control device 130 includes, for example, a computer equipped with an operation controller 132 and a storage 134.

The storage 134 stores a processing recipe that defines various processing sequences executed by the substrate processing system 100 and a control program for controlling various processes. The control device 130 controls operations of the substrate processing system 100 by reading and executing the processing recipe and the program stored in the storage 134.

The program may be recorded in a non-transitory computer-readable storage medium and installed from a storage medium in the storage 134 of the control device 130. Examples of the computer-readable storage medium may include a magnetic disk such as a hard disk drive (HDD) or a floppy disk (FD), an optical disc such as a compact disc (CD), a magneto-optical (MO) disk, a semiconductor memory such as a solid-state drive (SSD) or a memory card, and the like.

In the above-described substrate processing system 100, the first substrate transfer mechanism 114 takes the substrate W out of the FOUP 102 placed on the loading/unloading port 104 to load the same into the load lock chamber 110 (or 112). When the interior of the load lock chamber is depressurized to the medium vacuum, the second substrate transfer mechanism 122 takes the substrate W out of the load lock chamber 110 (or 112) to load the substrate W into a predetermined processing unit among the plurality of processing units 120. An interior of the respective processing unit 120 is depressurized to a high vacuum, and predetermined vacuum processing is performed in the interior of the processing unit 120. The substrate W that has been subjected to the predetermined vacuum processing in one or plural processing units 120 is loaded into the load lock chamber 110 (or 112) by the second substrate transfer mechanism 122. When the interior of the load lock chamber 110 (or 112) is increased to atmospheric pressure, the first substrate transfer mechanism 114 takes the processed substrate W out of the load lock chamber 110 (or 112) and stores the same in the original FOUP 102 placed on the loading/unloading port 104. In a series of operations described above, the gate valve G is appropriately opened and closed.

An overall configuration and operation of the substrate processing system 100 described above are well known in a multi-chamber-type vacuum processing system, and thus detailed descriptions thereof will be omitted. In addition, the overall configuration of the substrate processing system 100 described above is merely one example of a configuration of a substrate processing system which may incorporate the gas cluster cleaning unit 10 described below. Various modifications may be added to such a configuration example.

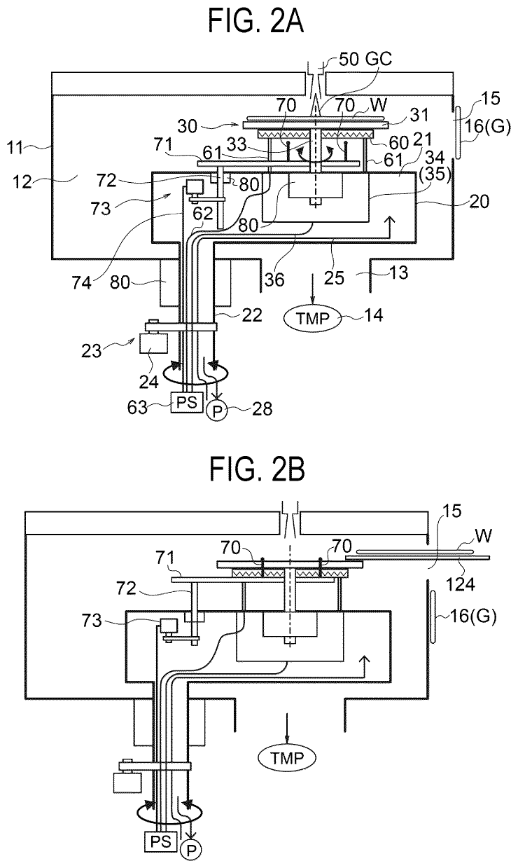

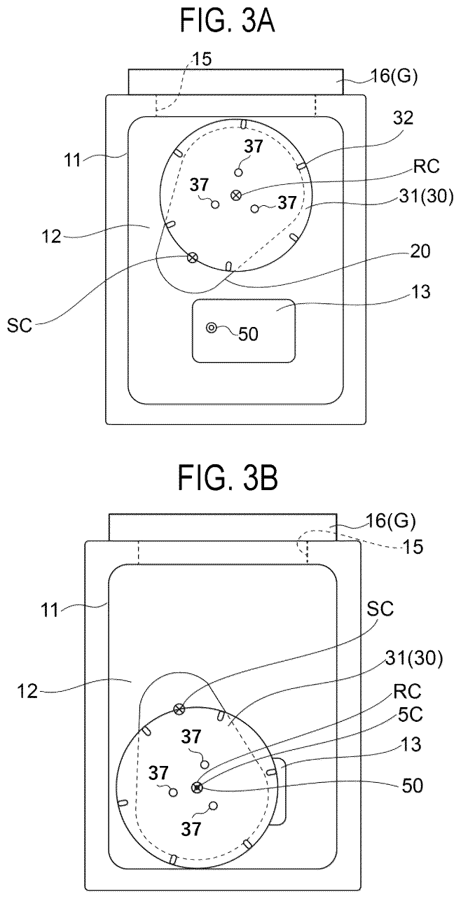

Next, one example of the configuration of the gas cluster cleaning unit 10 will be described with reference to FIGS. 2A and 2B, and FIGS. 3A and 3B. FIGS. 2A and 2B are longitudinal cross-sectional views schematically illustrating the configuration of the gas cluster cleaning unit 10. Herein, a horizontal positional relationship between constituent elements may be different from that of the actual gas cluster cleaning unit 10 in order to represent a plurality of constituent elements in the same cross section. The horizontal positional relationship between the constituent elements will be described with reference to FIGS. 3A and 3B.

The gas cluster cleaning unit 10 includes a processing container 11 configured as a vacuum processing chamber. A processing space (processing chamber) 12 is defined inside the processing container 11. An exhaust port 13 is provided in a bottom wall of the processing container 11. The processing space 12 may be depressurized to a high vacuum of about 1×10⁻⁵ Pa via the exhaust port 13 by a vacuum pump, for example, a turbo-molecular pump 14 (TMP).

An opening 15 is provided in one sidewall of the processing container 11. The opening 15 may be hermetically sealed by an air-tight door such as a gate valve 16 (corresponding to the gate valve G in FIG. 1). The substrate holder 124 of the second substrate transfer mechanism 122 (see FIG. 1) may load or unload the substrate W into or from the processing space 12 via the opening 15 with the gate valve 16 open while holding the substrate W.

A swivel housing 20 is provided inside the processing space 12. The housing 20 has an internal space 21 that is hermetically isolated from an atmosphere of the processing space 12. A hollow swivel shaft 22 extends vertically downward from a bottom surface of the housing 20. The swivel shaft 22 penetrates a bottom wall of the processing container 11 and extends outward of the processing container 11.

As illustrated in FIG. 2A, a swivel-shaft drive mechanism 23 for rotating the swivel shaft 22 around a vertical axis is provided outside the processing container 11. The swivel-shaft drive mechanism 23 may be constituted with, for example, an electric rotary motor 24 and a power transmission mechanism such as a transmission gear, a timing belt or the like. The electric rotary motor 24 may directly rotate the swivel shaft 22.

The electric rotary motor 24 may be any motor as long as it may accurately determine swivel angle positions of the swivel shaft 22 and the housing 20 coupled to the swivel shaft 22. For example, a stepping motor or a servo motor with a rotary encoder may be used as the electric rotary motor 24.

A rotational stage 30 is provided inside the processing space (processing chamber) 12. The substrate W to be processed is held by the rotational stage 30 in a horizontal posture in a state in which a surface (front surface) to be processed of the substrate W faces upward. As illustrated in FIG. 3A, the rotational stage 30 includes a disc-like plate 31 having approximately the same shape as the substrate W, and a plurality of (for example, six) substrate holding hooks 32 provided on a peripheral portion of the plate 31.

As illustrated in FIG. 2A, a rotary shaft 33 extends vertically downward from a bottom surface of the center of the plate 31. The rotary shaft 33 penetrates a ceiling wall of the housing 20 and extends into the internal space 21 of the housing 20. A rotation driver 34 configured to rotate the rotational stage 30 around a vertical axis is provided in the internal space 21 of the housing 20 and is fixed to a wall of the housing 20. The rotation driver 34 is constituted with, for example, an electric rotary motor 35, which is a driving force generation source. An extension portion of a rotational shaft of the electric rotary motor 35 may serve as the rotary shaft 33 of the rotational stage 30. Further, the rotational shaft of the electric rotary motor 35 and the rotary shaft 33 of the rotational stage 30 may be arranged coaxially and coupled to each other. Further, the electric rotary motor 35 may be configured to rotate the rotary shaft 33 via a power transmission mechanism (a gear box, a belt, and the like) arranged in the internal space 21 of the housing 20. The rotational stage 30, the rotary shaft 33, and the rotation driver 34 (the electric rotary motor 35) constitute a substrate holding/rotating mechanism.

By driving the electric rotary motor 35, the rotational stage 30 and the substrate W held thereon may be rotated around the vertical axis. The electric rotary motor 35 may have a function of positioning a rotational angle position of the rotational stage 30 and a function of adjusting a rotational speed of the rotational stage 30. For example, a stepper motor or a servo motor with a rotary encoder may be used as the electric rotary motor 35.

A gas nozzle 50 is provided on a ceiling wall of the processing container 11. The gas nozzle 50 injects gas (a CO₂ gas, a He gas, or the like) downward to irradiate a gas cluster (indicated by reference symbol GC in FIG. 2A) onto an upper surface of the substrate W held by the rotational stage 30.

In the embodiment illustrated herein, the gas nozzle 50 is firmly fixed to the ceiling wall of the processing container 11 such that the gas nozzle 50 is immovable. When the gas nozzle 50 vibrates, variation in a gas flow (i.e., movement of the cluster) occurs, which may result in variation in a processing result. By making the gas nozzle 50 immovable, the gas nozzle 50 does not vibrate as the gas nozzle moves. This provides an effect of stabilizing the processing result.

FIGS. 3A and 3B are plan views illustrating the processing container 11 in which the ceiling wall is removed, and major constituent elements provided in the interior of the processing container 11.

From a comparison of FIG. 3A and FIG. 3B, swiveling motions of the housing 20 and the rotational stage 30 coupled thereto by the swivel-shaft drive mechanism 23 may be understood. A swiveling axial line of the swiveling motion is indicated by reference symbol SC. By the swiveling motion, the rotational stage 30 may swivel around a vertical axis between a substrate delivery position (substrate transfer region) (a position illustrated in FIG. 3A, which is relatively close to the opening 15 of the processing container 11) and a processing position (substrate processing region) (a position illustrated in FIG. 3B, which is relatively far from the opening 15). In FIGS. 3A and 3B, a rotation axial line of the rotational motion of the rotational stage 30 is indicated by reference symbol RC.

In FIGS. 3A and 3B, a position directly below the gas nozzle 50 is indicated by a double circle with reference numeral 50. In FIG. 3B, since a position indicated by reference symbol RC and a position indicated by reference numeral 50 coincide with each other, it may be difficult to distinguish these positions.

When the gas cluster is irradiated from the gas nozzle 50 in the state of FIG. 3B, the gas cluster collides with the center of the substrate W (which coincides with the center of the rotational stage 30). In this state, any radial position on the surface of the substrate W may be positioned directly below the gas nozzle 50 by swiveling the rotational stage 30 about the swiveling axial line SC via the housing 20. In a configuration example illustrated in FIG. 3B, any radial position on the surface of the substrate W may be positioned directly below the gas nozzle 50 by swiveling the housing 20 and the rotational stage 30 approximately 45 degrees counterclockwise from the position illustrated in FIG. 3B.

By combining the swiveling motion about the swiveling axial line SC and the rotational motion about the rotational axis RC of the rotational stage 30, any position on the surface of the substrate W held by the rotational stage 30 may be positioned directly below the gas nozzle 50. In other words, the gas cluster may be irradiated onto the entire surface of the substrate W.

When processing the substrate W, a distance between the gas nozzle 50 and the surface of the substrate W may be reduced to increase an efficiency of the gas cluster cleaning. On the other hand, when the substrate W is loaded or unloaded into or from the processing container 11, a space is required to lift the substrate W by lift pins 70 described below. For this reason, the ceiling wall of the processing container 11 may be provided such that a vertical distance between the ceiling wall of the processing container 11 and the rotational stage 30 when the rotational stage 30 is at the substrate delivery position is greater than a vertical distance between the ceiling wall of the processing container 11 and the rotational stage 30 when the rotational stage 30 is at the processing position.

For example, in a case in which a mechanism configured to raise and lower the gas nozzle 50, or a mechanism configured to raise and lower the housing 20 or the rotational stage 30 is provided, swiveling angle ranges of the housing 20 and the rotational stage 30 may be set by shifting the rotational stage 30 by a distance approximately corresponding to a radius of the substrate W from the substrate delivery position. This makes it possible to further reduce a volume of the processing space 12. However, such a volume reduction is in a trade-off relationship with an increase in apparatus cost.

Further, two or more gas nozzles 50 may be provided on the ceiling wall of the processing container 11. In this case, in the plan view illustrated in FIG. 3B, the two gas nozzles may be arranged on a circumference with the swiveling axial line SC as the center and a line segment SCRC as a radius. In such a configuration, by appropriately combining the swiveling motion of the rotational stage 30 about the swiveling axial line SC and the rotational motion of the rotational stage 30 about the rotational axis RC, any position on the surface of the substrate W held by the rotational stage 30 may be positioned directly below each gas nozzle.

The same gas cluster may be irradiated from the two gas nozzles 50. In this case, one gas nozzle 50 may be used to irradiate the gas cluster onto a central region of the substrate W, and the other gas nozzle 50 may be used to irradiate the gas cluster onto a peripheral region of the substrate W. This makes it possible to reduce a time required to process one sheet of substrate W by almost half.

Different gas clusters may be irradiated from two or more gas nozzles 50. In this case, the gas cluster cleaning under different conditions may be performed by one gas cluster cleaning unit 10.

As illustrated in FIG. 2A, a disc-like heater 60 is provided below the plate 31 of the rotational stage 30. When electric current is supplied to the heater 60, the heater 60 generates heat, and the plate 31 is heated by thermal radiation from the heater 60. The substrate W held by the rotational stage 30 may be heated by the heated plate 31. The heater 60 is configured to be capable of substantially evenly heating the entire substrate W. For example, the heater 60 may be a resistance heater equipped with a heating element which extends in a meandering manner so as to cover the entire area of the plate 31.

The heater 60 is supported by a plurality of pillars 61 which stand on the ceiling wall of the housing 20. A power feeding line 62 for supplying power to the heater 60 may be provided inside each pillar 61. In one configuration example illustrated in FIG. 2A, the power feeding line 62 is drawn to the internal space 21 of the housing 20 via an interior of each pillar 61. The power feeding line 62 may be further drawn from the internal space 21 outward of the processing container 11 via an internal space of the hollow swivel shaft 22, and may be connected to a power supply device (PS) 63.

Although not illustrated, a detection signal line may be provided in parallel with the power feeding line 62. A detection signal obtained by a temperature sensor such as a thermocouple embedded in the heater 60 is sent to the power supply device 63 via control/detection signal lines. Then, a temperature controller incorporated in the power supply device 63 controls the power to be sent to the heater 60 via the power feeding line 62.

A plurality of lift pins 70 (three lift pins in this example) for raising and lowering the substrate W relative to the rotational stage 30 is provided below the plate 31 of the rotational stage 30 and below the heater 60. Lower ends of the lift pins 70 are fixed to a ring-like pin support 71. A lift rod (lifting body) 72 extends vertically downward from a lower surface of an extension portion that extends radially from a ring-like portion of the pin support 71. The lift rod 72 penetrates the ceiling wall of the housing 20 and extends to the internal space 21 of the housing 20. A lifting drive mechanism 73 for raising and lowering the lift rod 72 is provided in the internal space 21. The lifting drive mechanism 73 is constituted with an appropriate linear actuator, for example, a ball screw. The lifting drive mechanism 73 may be constituted with an air cylinder. When the ball screw is used as the lifting drive mechanism 73, it is desirable to construct the lifting drive mechanism 73 may be constructed such that the lift rod 72 does not rotate while facilitating sealing of the lift rod 72 (which will be described later).

As illustrated in FIG. 2B, by raising the lift pin 70 using the lifting drive mechanism 73, the lift pin 70 may be positioned at a raised position at which an upper end of the lift pin 70 protrudes upward from an upper surface of the plate 31 of the rotational stage 30. As illustrated in FIG. 2A, by lowering the lift pin 70 using the lifting drive mechanism 73, the lift pin 70 may be positioned at a position at which the lift pin 70 does not interfere with the rotation of the rotational stage 30, preferably, at a lowered position at which the upper end of the lift pin 70 is positioned below a lower surface of the heater 60.

Through-holes through which the lift pins 70 pass respectively when they are raised and lowered are provided in the plate 31 and the heater 60 (although they not illustrated in FIGS. 2A and 2B). In FIGS. 3A and 3B, the through-holes for the lift pins 70 provided in the plate 31 are indicated by reference numeral 37. Even in the heater 60, the same through-holes as the through-holes 37 are provided at positions directly below the through-holes 37.

When the substrate W is loaded into the processing container 11, the rotational stage 30 is positioned at the substrate delivery position (a position illustrated in FIG. 3A), and the lift pins 70 are positioned at the raised position (the position illustrated in FIG. 2A). In this state, the substrate holder 124 of the second substrate transfer mechanism 122 holding the substrate W enters the processing space 12 via the opening 15 with the gate valve 16 open, and the substrate W held by the substrate holder 124 is positioned directly above the rotational stage 30. Subsequently, the lift pins 70 are further raised such that the substrate holder 124 lifts the substrate W. Thereafter, the substrate holder 124 is withdrawn from the processing space 12. Subsequently, the substrate W is delivered onto the rotational stage 30 while the lift pins 70 are lowered to a lowered position. Alternatively, the substrate holder 124 of the substrate transfer mechanism 122 holding the substrate W directly above the rotational stage 30 may be lowered to place the substrate W on the lift pins 70 at the raised position, thereby delivering the substrate W from the substrate holder 124 to the lift pins 70. That is, the delivery of the substrate W between the substrate holder 124 and the lift pins 70 may be performed by raising and lowering the lift pins 70 or by raising and lowering the substrate holder 124. When the substrate W is unloaded from the processing container 11, a reverse operation to the above-described operation is performed.

The internal space 21 of the housing 20 is in communication with an internal atmosphere (atmospheric atmosphere) of a clean room in which the substrate processing system 1 is installed, via the hollow swivel shaft 22. Therefore, the internal space 21 of the housing 20 is always maintained at an atmospheric atmosphere (normal pressure). On the other hand, during the operation of the substrate processing system 1, the interior of the processing container 11, i.e., the processing space 12, is maintained at a depressurized atmosphere. For example, the processing space 12 is set to a medium vacuum (i.e., the same vacuum level as that of the interior of the vacuum transfer chamber 118 (FIG. 1)) when the substrate W is loaded into or unloaded from the processing space 12, and is set to a high vacuum when the substrate is processed inside the processing space 12. In any case, there is a large pressure difference between the processing space 12 of the processing container 11 and the internal space 21 of the housing 20 (or an external space of the processing container 11).

For this reason, it is necessary to apply vacuum seal to movable members (specifically, the rotary shaft 33 of the rotational stage 30, and the lift rod 72 configured to raise and lower the lift pins 70) which extend through the wall of the housing 20, and a movable member (specifically, the swivel shaft 22 of the housing 20) which extends through the wall of the processing container 11. The vacuum seal may be appropriately selected from vacuum seals known in the technical field of the present disclosure.

In FIG. 2A, the vacuum seal is indicated by reference number 80. For example, in the housing 20, a portion through which the swivel shaft 22 passes and a portion through which the rotary shaft 33 passes may be sealed by the vacuum seal 80 made of a magnetic fluid seal. The lift rod 72 performs only a slide motion. Thus, the lift rod 72 may be sealed by the vacuum seal 80 made of an O-ring (preferably, a plurality of O-rings arranged in series in an axial direction of the lift rod 72). Further, a sealed portion of the lift rod 72, which is sealed by the O-ring, is a smooth cylindrical portion.

The internal space 21 of the housing 20 is kept at the atmospheric atmosphere. Thus, a driving force source (the electric rotary motor 35) of the rotation driver 34 and a driving force source (for example, the electric rotary motor for the ball screw) of the lifting drive mechanism 73 may be cooled using air as a cooling medium. Therefore, the driving force sources may be cooled more efficiently than when the driving force sources are arranged in a vacuum. In addition, inexpensive driving force sources (compared to those designed for use in the vacuum atmosphere) designed for use in the atmospheric atmosphere may be used. In addition, by arranging the driving force sources in a space isolated from the processing space 12, it is possible to prevent the processing space 12 from being contaminated by dust (particle-causing substances) generated by the driving force sources.

In order to promote the air cooling of the driving force sources, a configuration may be adopted in which cooling air is suctioned to and exhausted from the internal space 21 of the housing 20 via the hollow swivel shaft 22. Specifically, for example, the internal space 21 of the housing 20 is suctioned and exhausted via the internal space of the hollow rotating shaft 26 using an exhaust mechanism 28 such as an exhaust fan or an ejector. A tube 25, which is open at one end to the atmospheric atmosphere and at the other end to the internal space 21 of the housing 20 (preferably an inner side of the housing 20), may be installed inside the hollow swivel shaft 22.

The power feeding line and the control/detection signal lines (which are indicated by reference number 36 in FIG. 2A) connected to the electric rotary motor 35 may pass through the internal space of the hollow swivel shaft 22. Further, a power feeding line and control/detection signal lines (which are indicated by reference number 74 in FIG. 2A) connected to the linear actuator of the lifting drive mechanism 73 may pass through internal space of the hollow swivel shaft 22. The control/detection signal lines 36 and 74 are connected to the power supply device 63. The rotational angle position of the rotational table 30 and a height position of the lift rod 72 are controlled via a controller incorporated in the power supply device 63.

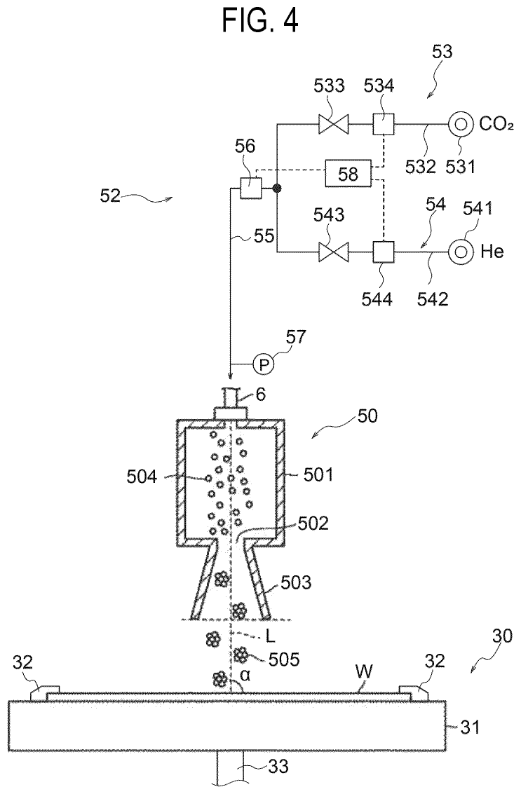

The gas nozzle 50 and the gas supply mechanism 52 configured to supply the gas to the gas nozzle 50 may adopt known ones. Examples of these constituent elements will be described below with reference to FIG. 4.

The gas nozzle 50 includes a substantially cylindrical pressure chamber 501. An orifice 502 having an opening diameter of, for example, about 0.1 mm is provided at a lower end portion of the pressure chamber 501. A gas diffusion portion 503, a diameter of which increases downward, is connected to the orifice 502.

The gas supply mechanism 52 includes a CO₂ gas (carbon dioxide gas) supplier 53 and a He gas (helium gas) supplier 54. The CO₂ gas supplier 53 includes a CO₂ gas supply path 532 connected to a CO₂ gas source 531, and an opening/closing valve 533 and a flow rate control valve 534 which are provided in the CO₂ supply path 532. The He gas supplier includes a He gas supply path 542 connected to a He gas source 541, and an opening/closing valve 543 and a flow rate control valve 544 which are provided in the He gas supply path 542.

The CO₂ gas supply path 532 and the He gas supply path 542 are joined to constitute a gas supply path 55. A downstream end of the gas supply path 55 is connected to an upper end portion of the pressure chamber 501 of the gas nozzle 50. A pressure control valve 56 is provided in the gas supply path 55. A pressure sensor 57 is provided in the gas supply path 55 to detect an internal pressure of the gas supply path 55. The pressure sensor 57 may detect an internal pressure of the pressure chamber 501 of the gas nozzle 50. A controller 58 for the gas supply mechanism 52 adjusts an opening degree of the pressure control valve 56 so that the pressure detected by the pressure sensor 57 reaches a predetermined value. Thus, the internal pressure of the pressure chamber 501 of the gas nozzle 50 is controlled to a desired value. In addition, the controller 58 controls a mixing ratio of the CO₂ gas and the He gas by adjusting the opening degrees of the flow rate control valves 534 and 544.

The orifice 502 is provided in the gas nozzle 50. Thus, when the gas is injected from the gas nozzle 50 into the depressurized processing space 12, a significant pressure drop occurs at the orifice 502. As a result, the gas passing through the orifice 502 undergoes adiabatic expansion. Thus, a gas cluster 505, which is an aggregate of atoms or molecules 504 of a cleaning gas (the CO₂ gas in this example), is generated. The He gas is a gas for accelerating a gas flow, i.e., the gas cluster. The He gas hardly forms the cluster. Thus, the He gas may be mixed with the CO₂ gas to increase a speed of the cluster generated from the CO₂ gas. When the gas clusters 505 collide with the surface of the substrate W, contaminants such as particles adhering to the surface of the substrate W may be blown by a kinetic energy of the gas cluster 505.

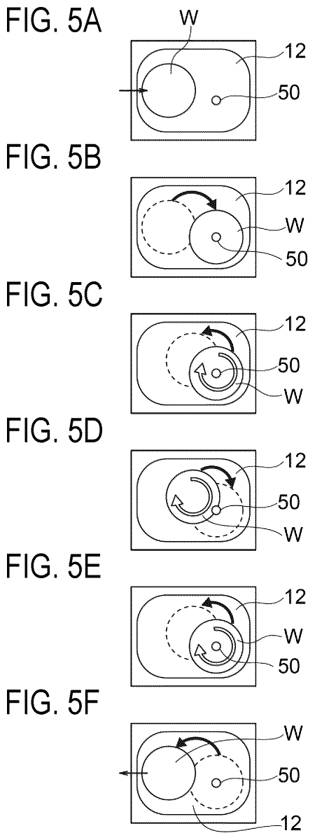

The gas nozzle 50 is provided to irradiate the gas clusters 504 are irradiated substantially perpendicularly to the surface of the substrate W. Herein, the expression “substantially perpendicularly” means that, as illustrated in FIGS. 5A to 5F, an angle α between a track directional vector of a main flow of the gas cluster when the gas cluster is incident on the surface of the substrate W and the surface of the substrate W held by the rotational stage 30 is in a range of 90 degrees±15 degrees.

In order to irradiate the gas clusters substantially perpendicularly to the surface of the substrate W, the gas nozzle 50 may be provided so that the angle α between a central axis line of an outlet of the gas nozzle 50 and the surface of the substrate W is in the range of 90 degrees±15 degrees. In a modification, the gas cluster discharged from the gas nozzle 50 may be ionized midway and an electric field may be applied to the ionized gas cluster to change the track of the gas cluster. Even in this case, the angle α between the track directional vector of the main flow of the gas cluster when the gas cluster is incident on the surface of the substrate W and the surface of the substrate W held by the rotational stage 30 may be in the range of 90 degrees±15 degrees.

In the present specification, an operation of the gas nozzle 50 will be described based on a premise that the gas nozzle 50 discharges the gas vertically downward and the gas cluster is substantially perpendicularly incident on the surface of the substrate W in a horizontal posture.

As illustrated in FIG. 3A, the exhaust port 13 of the processing container 11 may be located directly below the gas nozzle 50. With this configuration, when dummy dispense of gas is performed from the gas nozzle 50, the gas is quickly discharged from the processing space 12. Even when two or more gas nozzles 50 are provided, it is desirable that the opening of the exhaust port 13 is located directly below each gas nozzle 50.

The gas cluster irradiated from the gas nozzle 50 returns to gas molecules after colliding with the substrate W. Gas molecules remaining in the vicinity of the surface of the substrate W reduce the kinetic energy of the gas cluster by colliding with the gas cluster. When the exhaust port 13 is located below the substrate W, the gas molecules derived from the gas cluster may be quickly removed from the vicinity of the surface of the substrate W. When the exhaust port 13 of the processing container 11 is provided directly below the gas nozzle 50, it is located below the substrate W held by the rotational stage 30 at the processing position.

An example of a processing procedure performed by the gas cluster cleaning unit 10 will be described below with reference to FIGS. 3A and 3B, and FIGS. 5A to 5F. The following procedure is executed by the control device 130 (see FIG. 1) controlling the operations of the constituent elements of the gas cluster cleaning unit 10. FIGS. 5A to 5F schematically illustrate a transition of a positional relationship between the processing space 12, the substrate W, and the gas nozzle 50 as viewed from directly above.

First, the substrate W is loaded into the processing container 11 and is held by the rotational stage 30 at the substrate delivery position (FIG. 3A and FIG. 5A).

Subsequently, the housing 20 and the rotational stage 30 are swiveled to locate the center of the substrate W at a position (the substrate processing position) directly below the outlet of the gas nozzle 50 (FIG. 3B, and FIGS. 5A and 5B).

Subsequently, the substrate W begins to rotate, and the gas nozzle 50 begins the irradiation of the gas cluster. While continuing the rotation of the substrate W and the irradiation of the gas cluster from the gas nozzle 50, the housing 20 and the rotational stage 30 are swiveled counterclockwise until a peripheral portion of the substrate W is located directly below the outlet of the gas nozzle 50. An irradiation position of the gas cluster on the surface of the substrate W is moved from the center of the substrate W to the peripheral portion of the substrate W over, for example, 30 seconds (FIGS. 5C and 5D).

Subsequently, while continuing the rotation of the substrate W and the irradiation of the gas cluster from the gas nozzle 50, the housing 20 and the rotational stage 30 are rotated in an opposite direction, and the irradiation position of the gas cluster on the surface of the substrate W is moved from the peripheral portion of the substrate W to the center of the substrate W over, for example, 30 seconds (FIGS. 5D and 5E). As a result, the gas cluster is irradiated over the entire surface of the substrate W so that the gas cluster cleaning ends.

Thereafter, the housing 20 and the rotational stage 30 are swiveled to the substrate delivery position where the substrate W is unloaded from the processing container 11 (FIG. 5F).

According to the above embodiment, all of the driving force sources of the mechanisms for moving (rotating, swiveling, raising and lowering, and the like) the substrate W are disposed at a position that is not exposed to the internal atmosphere of the processing space 12 (inward of the housing 20 or outward of the processing container 11). This eliminates a need to use expensive driving force sources intended for use in the vacuum atmosphere. That is, inexpensive driving force sources may be used. In addition, since all of the driving force sources of the mechanisms for moving the substrate W are disposed in the atmospheric atmosphere, it is possible to cool (release heat from) the driving force sources using air as a heat transfer medium. In other words, such a cooling may be performed at a lower cost than when heat conduction in the vacuum atmosphere is performed. In addition, dust (particle-causing substances) from the driving force sources is not introduced into the processing space 12. This makes it possible to prevent the contamination of the substrate W.

In the above embodiment, by combining the rotational motion of the rotational stage 30 and the swiveling motion of the housing 20 (which causes the housing 20 to move in the horizontal direction), the irradiation of the gas clusters to any position on the surface of the substrate W is possible. However, the present disclosure is not limited thereto. The housing 20 may translate in the horizontal direction.

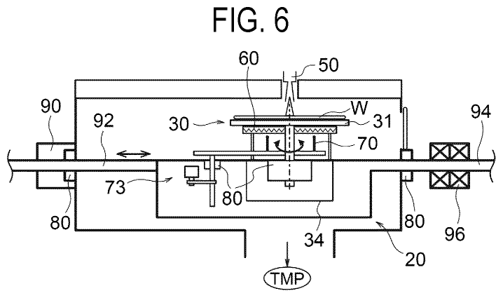

Specifically, for example, as illustrated in FIG. 6, a linear motion mechanism 90 may be provided on one sidewall of the housing 20. As an example, the linear motion mechanism 90 may include a linear actuator such as a ball screw (not illustrated), which is driven by an electric motor (driving force source) (not illustrated), and a driving rod 92 which moves forward and backward in the horizontal direction by the linear actuator. The driving rod 92 extends horizontally via the sidewall of the processing container 11. A tip of the driving rod 92 is fixed to the housing 20.

A hollow driven rod 94 is provided on the other sidewall of the housing 20. The driven rod 94 extends horizontally via the sidewall of the processing container 11. A tip of the driven rod 94 is fixed to the housing 20. The driven rod 94 is supported by a linear bearing 96.

A portion of the sidewall of the housing 20 through which the driving rod 92 and the driven rod 94 pass is sealed by a vacuum seal 80 (which is constituted with, for example, a plurality of O rings arranged in series in an axial direction of the driving rod 92 and the driven rod 94).

By moving the driving rod 92 forward and backward in the horizontal direction, the housing 20 and various devices attached thereto (the rotational stage 30, the lift pins 70 and the drive mechanisms thereof, the heater 60, and the like) may be moved together in the horizontal direction. By combining the horizontal translational motion of the housing 20 and the rotational motion of the rotational stage 30, any position on the surface of the substrate W may be located directly below the gas nozzle 50 and the gas cluster may be irradiated to the respective position.

The power feeding lines and the control/detection signal lines may pass through an internal space of the hollow driven rod 94 like the internal space of the hollow swivel shaft 22. Further, the internal space of the hollow driven rod 94 may be used to suction and exhaust the internal space 21 of the housing 20.

Even in Modification illustrated in FIG. 6, substantially the same effects as the embodiment illustrated in FIG. 2A may be obtained.

According to the present disclosure in some embodiments, it is possible to suppress a substrate from being contaminated by particles generated from a drive mechanism for moving the substrate.

It should be noted that the embodiments and the modification disclosed herein are exemplary in all aspects and are not restrictive. The above-described embodiments may be omitted, replaced, or modified in various forms without departing from the scope and spirit of the appended claims.

The substrate to be processed is not limited to a semiconductor wafer and may be various substrates used in the field of semiconductor device manufacturing, such as glass substrates and ceramic substrates.

What is claimed is:

1. A substrate processing apparatus, comprising:
a processing container having a processing space provided in an interior of the processing container, which is depressurized to a pressure lower than atmospheric pressure, and an opening through which a substrate is loaded into and unloaded from the processing space;
a substrate holding/rotating mechanism configured to hold the substrate in a horizontal posture and rotate the substrate around a vertical axis, and including a substrate holder configured to hold the substrate inside the processing space and a driving force source configured to generate a driving force for rotationally driving the substrate holder;
a housing having an internal space hermetically isolated from the processing space, wherein the driving force source of the substrate holding/rotating mechanism is accommodated in the internal space;
a horizontal movement mechanism configured to move the housing in a horizontal direction so as to move the substrate holder in the horizontal direction; and
a gas nozzle configured to inject a gas so as to irradiate a gas cluster onto an upper surface of the substrate held by the substrate holder.

2. The substrate processing apparatus of claim 1, wherein the horizontal movement mechanism includes a swivel mechanism configured to swivel the housing around a swiveling axial line extending in a vertical direction to swivel the substrate holder.

3. The substrate processing apparatus of claim 1, wherein the horizontal movement mechanism includes a linear movement mechanism configured to linearly move the housing so as to linearly move the substrate holder.

4. The substrate processing apparatus of claim 1, wherein the internal space of the housing is in communication with an external space of the processing container.

5. The substrate processing apparatus of claim 1, further comprising: an exhaust mechanism configured to exhaust an atmosphere of the internal space of the housing.

6. The substrate processing apparatus of claim 2, wherein the swivel mechanism has a hollow swivel shaft extending downward from the housing to an outer side of the processing container, and
wherein the internal space of the housing is in communication with an outer space of the processing container through an internal space of the hollow swivel shaft.

7. The substrate processing apparatus of claim 6, further comprising: an exhaust mechanism configured to exhaust an atmosphere of the internal space of the housing via the internal space of the hollow swivel shaft.

8. The substrate processing apparatus of claim 6, wherein a power feeding line configured to supply power to the driving force source of the substrate holding/rotating mechanism extends from an outside of the processing container to the internal space of the housing via the internal space of the hollow swivel shaft.

9. The substrate processing apparatus of claim 1, further comprising:
a plurality of lift pins configured to support the substrate by upper ends of the plurality of lift pins; and
a lifting drive mechanism configured to raise and lower the substrate relative to the substrate holder by raising and lowering the plurality of lift pins relative to the substrate holder,
wherein at least the driving force source of the lifting drive mechanism is accommodated in the housing.

10. The substrate processing apparatus of claim 1, wherein the gas nozzle is fixed to the processing container such that the gas nozzle is immovable.

11. The substrate processing apparatus of claim 10, wherein an exhaust port configured to vacuum-suction the processing space is provided to be open immediately below the gas nozzle.

12. The substrate processing apparatus of claim 1, further comprising:
a control device configured to control at least operations of the driving force source of the substrate holding/rotating mechanism, the horizontal movement mechanism, and a gas supply mechanism configured to supply the gas to the gas nozzle,
wherein the control device controls the operations of the driving force source of the substrate holding/rotating mechanism and the horizontal movement mechanism, when the gas cluster is irradiated onto the substrate from the gas nozzle, to sequentially irradiate the gas cluster onto an irradiation target region of the upper surface of the substrate.

13. The substrate processing apparatus of claim 9, further comprising:
a control device configured to control at least operations of the driving force source of the substrate holding/rotating mechanism, the horizontal movement mechanism, and a gas supply mechanism configured to supply the gas to the gas nozzle,
wherein a substrate delivery region relatively close to the opening and a substrate processing region relatively far from the opening are set in the processing space, and
wherein the control device executes:
controlling the operation of the horizontal movement mechanism and an operation of the lifting drive mechanism to deliver the substrate to a rotational stage from an external substrate transfer mechanism using the plurality of lift pins by positioning the substrate holder in the substrate delivery region;
controlling the operation of the horizontal movement mechanism to position the substrate holder in the substrate processing region;
controlling the operations of the driving force source of the substrate holding/rotating mechanism and the horizontal movement mechanism, while controlling the irradiating of the gas cluster onto the substrate from the gas nozzle, to sequentially irradiate the gas cluster onto an irradiation target region of the upper surface of the substrate; and
controlling the operations of the horizontal movement mechanism and the lifting drive mechanism to return the substrate holder to the substrate delivery region and deliver the substrate from the substrate holder to the external substrate transfer mechanism using the plurality of lift pins.

14. A substrate processing method executed using a substrate processing apparatus,
wherein the substrate processing apparatus includes:
a processing container having a processing space provided in an interior of the processing container, which is depressurized to a pressure lower than atmospheric pressure, and an opening through which a substrate is loaded into and unloaded from the processing space;
a substrate holding/rotating mechanism configured to hold the substrate in a horizontal posture and rotate the substrate around a vertical axis, and including a substrate holder configured to hold the substrate inside the processing space and a driving force source configured to generate a driving force for rotationally driving the substrate holder;
a housing having an internal space hermetically isolated from the processing space, wherein the driving force source of the substrate holding/rotating mechanism is accommodated in the internal space;
a horizontal movement mechanism configured to move the housing in a horizontal direction so as to move the substrate holder in the horizontal direction; and
a gas nozzle configured to inject a gas so as to irradiate a gas cluster onto an upper surface of the substrate held by the substrate holder,
wherein the substrate processing method comprises:
irradiating the gas cluster onto the substrate held by the substrate holder from the gas nozzle; and
controlling operations of the driving force source of the substrate holding/rotating mechanism and the horizontal movement mechanism, when the gas cluster is irradiated onto the substrate, to sequentially irradiate the gas cluster onto an irradiation target region of the upper surface of the substrate.
